(19) United States
(12) Patent Application Publication
(10) Pub. No.: US 2010/0158067 A1
(43) Pub. Date: Jun. 24, 2010

(54) OPTICAL MODULE

(75) Inventors: Shinichi NAKATSUKA, Hino (JP); Yasunobu MATSUOKA, Hachioji (JP)

Correspondence Address: MATTINGLY & MALUR, P.C., 1800 DIAGONAL ROAD, SUITE 370, ALEXANDRIA, VA, 22314, US

(73) Assignee: HITACHI, LTD., Tokyo (JP)

(21) Appl. No.: 12/633,030

(22) Filed: Dec. 8, 2009

(30) Foreign Application Priority Data
Dec. 22, 2008 (JP) 2008-324917

(51) Int. Cl. H01S 5/42; H01S 5/183; H01S 5/20; H01S 5/026; G02B 6/42

(52) U.S. Cl. 372/50.124; 372/50.23; 385/15

(57) ABSTRACT

An optical module comprising a laser device adapted to emit a laser beam from a convex surface and including a horizontal resonator surface-emitting structure provided with a first lens through which an optical axis of the laser beam passes, and a second lens through which the laser beam having passed through the first lens passes, a surface opposed to the second lens-provided surface and the surface provided with the first lens being bonded together through a first adhesive transparent to the laser beam.

### CLAIM OF PRIORITY

The present application claims priority from Japanese patent application JP 2008-324917 filed on Dec. 22, 2008, the content of which is hereby incorporated by reference into this application.

### FIELD OF THE INVENTION

The present invention relates to an optical module having a lens-integrated semiconductor laser device.

### BACKGROUND OF THE INVENTION

In connection with a lens-integrated composite optical device there have been known such conventional techniques as those described in JP-A-2002-26452, JP-A-2004-311861, and JP-T-2001-519601.

The structure described in JP-A-2002-26452 is shown in FIG. 17. This structure is provided with a VCSEL array substrate with vertical cavity surface emitting lasers arranged thereon and a lens array substrate integral with the VCSEL array substrate, the lens array substrate having lenses formed at positions corresponding to the surface emitting lasers. The VCSEL array substrate and the lens array substrate are fabricated precisely by a photolithograph process. The lens array substrate is formed directly on the VCSEL array substrate and lenses are arranged thereon correspondingly to the position of the array element. Thus, according to the patent document in question, a displacement between the VCSEL array substrate and the lens array substrate can be prevented by accurate alignment of both substrates without the need of optical adjustment.

The structure described in JP-A-2004-311861 is shown in FIG. 18. A first hybrid integration devices having an arrayed configuration of plural surface emitting devices on a plane and a second hybrid integration devices having an arrayed configuration of plural optical devices on a plane are joined together. In this method, according to the patent document in question, the first and second hybrid integration devices are joined together after alignment between the two, then the thus-joined hybrid integration devices are cut into individual parts for separation into plural composite optical devices, whereby composite optical devices each having desired characteristics can be implemented in high reproducibility.

The structure described in JP-T-2001-519601 is shown in FIG. 19. According to the technique disclosed therein, plural wafers including a structure for holding integrated light emitting devices and having plural optical parts formed integrally are joined together, thereafter the wafers are separated and light emitting devices are attached to the light emitting device holding structure, thereby affording composite optical devices.

### SUMMARY OF THE INVENTION

In the conventional lens-semiconductor light emitting device integral combination, a limit is encountered in both alignment between light emitting devices and optical parts and also in the light focusing performance of micro lenses, and in coupling with an optical fiber for optical communication it has been difficult to obtain low coupling loss of 1 dB or less (20% or less).

However, in the conventional optical communication using laser beam as a signal carrier, a coupling loss of 1 dB or so does not arise a serious problem insofar as the light intensity of a light source used is sufficient, and even with use of the foregoing conventional techniques it has been possible to attain a satisfactory system performance.

With the recent great increase in communication capacity and expansion of applications which directly utilize the light energy of, for example, fiber amplifiers, a demand exists to lower the coupling loss for an optical fiber. If such a lens-integrated type light source is applied to application systems such as optical disc, laser direct exposure, and laser printer, this is effective in both improving the device performance and lowering cost and power consumption. With the composite optical devices obtained by the conventional techniques, it has been difficult to satisfy a highly accurate light focusing performance required in those devices.

In the above patent document JP-A-2002-26452, when forming micro lenses on the same wafer as that of light emitting devices, the alignment accuracy between the devices formed on both surface and back surface of a wafer encounters a limit of 1 μm or so. Optical axes of laser beams collimated by lenses undergo variations of 15′ to 30′. Moreover, the micro lenses formed on such a semiconductor crystal are inferior in lens performance to bulk lenses due to the problem associated with the semiconductor micropatterning accuracy. An astigmatism exceeded λ/2 in terms of wave front.

On the other hand, in the case where the light emitting devices and lenses described in the above patent documents JP-A-2004-311861 and JP-T-2001-519601 are affixed onto separate substrates and the substrates are laminated together, a dislocation error of about 4 μm occurs unavoidably, which corresponds to an angular misalignment of about 1° to 2° in terms of a radiation angle.

For solving the above-mentioned problems the lens-integrated composite optical device of the present invention includes a structure for radiating a laser beam in a direction perpendicular to a substrate surface of a first substrate, the laser beam radiating structure being provided on the first substrate, a first lens structure provided on a surface opposed to the structure-provided surface, the first lens structure having an optical axis approximately the same as that of the laser beam radiating structure, and a second lens provided on a second substrate made of a member transparent to the laser beam and separate from the first substrate, the second lens having an optical axis approximately the same as that of the first lens, the surface opposed to the second lens-provided surface and the first lens-provided surface being bonded together through an adhesive transparent to the laser beam.

At a focal length, f, of the first lens and a thickness, a, of the first substrate, a dislocation, x, caused by a registration error of the first lens as seen from the second lens is enlarged to 1/(1−a/f) times. On the other hand, the distance between the first lens and a light emitting point as seen from the second lens also becomes 1/(1−a/f), so that a positional margin of the first lens also becomes 1/(1−a/f) times. Accordingly, the spread accuracy of collimated light can be improved by adopting such a configuration in the range wherein 1/(1−a/f) exceeds the ratio of a positional accuracy of a cemented lens to that of an integrally-formed lens.

In this structure, by using as at least one of the first and second lenses a diffraction lens which fulfills its lens function by utilizing the diffraction of light, it has been possible to design the diffraction lens so as to correct aberration which is unavoidable in view of the structure of a convex lens.

In order to improve the quality of beam in such a laminated structure, the use of a gelatinous material capable of retaining flexibility has also been effective as the adhesive for bonding the first and second substrates.

However, in the case where the lens alignment accuracy is improved by the configuration described above, the focal depth becomes shallower. More particularly, a problem has occurred such that the accuracy for a light emitting point affording a good parallel beam and for the light transmitting direction of lens becomes stricter. Such an alignment can be adjusted in a process of assembling both individual light emitting devices and optical parts. But in the case of a composite optical device formed integrally with a wafer there has been no other solution than controlling the wafer thickness and roll strictly. In the case where two substrates to be laminated together are formed of different materials, such thickness and roll control is more difficult due to a difference in thermal expansion coefficient and a difference in surface hardness. The present inventor has solved this problem by disposing between the first and second substrates a member adapted to undergo an elastic deformation under pressure exerted between both substrates and thereby permitting fine adjustment of the substrate spacing. As such a substrate spacing adjusting member the present inventor uses a porous resin such as metal formed by plating and adapted to bend vertically to fulfill a spring function or sponge having 50% or more of pores in the interior thereof.

In such a structure there is used a second adhesive for fixing the spacing between the first and second substrates so that the component members are fixed completely after the final positioning. More specifically, the second adhesive is an UV curing resin or vulcanized silicone. By forming plural such light emitting device-lens combinations on one and same chip and by focusing of laser beams emitted from the light emitting devices to one spatial point it is possible to obtain a laser beam of a high energy density. These light emitting devices are preferably surface emitting lasers or semiconductor lasers each having an optical resonator in a direction horizontal to a substrate surface with 45° tilted mirrors integrated thereon.

According to the present invention a laser beam high in both beam parallelism and beam-condensability can be attained by integrated light emitting devices, thus making it possible to simplify the optical system which handles laser beam and also possible to attain the reduction of cost. With the configuration of focusing laser beams to one spatial point it becomes possible to obtain a high density laser beam by a single device.

### BRIEF DESCRIPTION OF THE DRAWINGS

FIG. 1 illustrates a wafer structure in a first embodiment of the present invention;

FIG. 2 illustrates the structure of a light emitting device in the first embodiment;

FIG. 3 illustrates the structure after machining a back surface in the first embodiment;

FIG. 4 illustrates a method for fabricating a plated spring in the first embodiment;

FIG. 5 illustrates the structure of the plated spring in the first embodiment;

FIG. 6 illustrates the structure of a light emitting composite optical device in the first embodiment;

FIG. 7 illustrates a wafer structure in a second embodiment of the present invention;

FIG. 8 illustrates the structure of a light emitting device in the second embodiment;

FIG. 9 illustrates the structure of a light emitting composite optical device in the second embodiment;

FIG. 10 illustrates a wafer structure in a third embodiment of the present invention;

FIG. 11 illustrates the structure of a light emitting device in the third embodiment;

FIG. 12 illustrates a wafer structure in a fourth embodiment of the present invention;

FIG. 13 illustrates the structure of a light emitting device in the fourth embodiment;

FIG. 14 illustrates the structure of a light emitting composite optical device in the fourth embodiment;

FIG. 15 illustrates the structure of a light emitting device in the fifth embodiment;

FIG. 16 illustrates the structure of a light emitting composite optical structure in the fifth embodiment;

FIG. 17 illustrates a conventional lens-integrated semiconductor laser;

FIG. 18 illustrates a conventional lens lamination type semiconductor laser; and

FIG. 19 illustrates a conventional wafer level integrated type optical device.

### DETAILED DESCRIPTION OF THE PREFERRED EMBODIMENTS

The semiconductor light emitting device of the present invention will be described below in more detail by way of embodiments of the invention illustrated in the drawings.

### First Embodiment

A first embodiment of the present invention will be described below in accordance with a device fabricating procedure. In this first embodiment, the semiconductor light emitting device is constructed as an AlGaInAs-based surface emitting type semiconductor laser with a wavelength of 1300 nm.

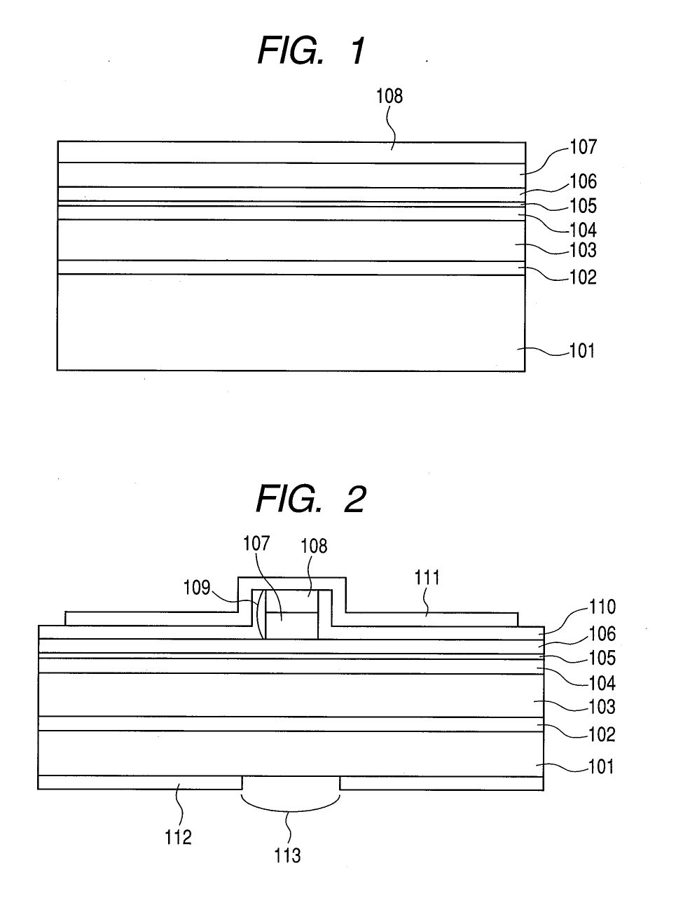

First, such single-crystal multilayers as shown in FIG. 1 are formed on an n-InP substrate 101 by metal organic chemical vapor deposition. More specifically, an n-InP buffer layer 102 and an n-type Bragg reflector 103 having a ¼ thick wavelength, which lattice-matches InP, are formed first. The n-type Bragg reflector 103 is constituted by a laminated film of n-InGaAs and n-InAlAs and has a reflectance of 99.8%. Subsequently, an n-InGaAlAs lower SCH (Separate Confinement Heterostructure) layer 104 lattice-matched with InP, a strained quantum well active layer 105 composed of an InGaAlAs strained barrier layer (band gap 1.32 eV, barrier layer thickness 8 nm) and an InGaAlAs strained quantum well layer (band gap 0.87 eV, well layer thickness 6 nm), a p-InGaAlAs upper SCH layer 106 lattice-matched with InP, a p-type Bragg reflector 107, and a p-InGaAs cap layer 108, are formed in order. The p-type Bragg reflector 107 is formed by a laminated film of p-InGaAs and p-InAlAs and has a reflectance of 99.2%.

Next, this wafer is processed into such a surface emitting laser structure as shown in FIG. 2. First, with an insulating film or the like as a mask, there is formed a post-like protrusion 109 by photoetching. For the etching, any method may be adopted. In addition to photoetching, there also may be adopted, for example, a wet process, RIE (Reactive Ion Etching), RIBE (Reactive Ion Beam Etching), or ion milling. Etching is performed so as to stop halfway of the p-type Bragg reflector 107 lest it should reach the strained quantum well active layer 105.

In the above structure, a silicon oxide film 110 for surface protection is formed and then removed from only an upper surface of the post-like protrusion 109. Thereafter, a p-type ohmic contact 111 is formed on an upper surface of the cap layer 108. Further, the substrate 101 is polished to a thickness of about 100 μm and thereafter an n-type ohmic contact 112 is formed on a back surface of the substrate 101. At this time, a back portion of the substrate 101 opposed to the post-like protrusion 109 is masked with an oxide beforehand and the n-ohmic electrode 112 is removed to form a through hole 113.

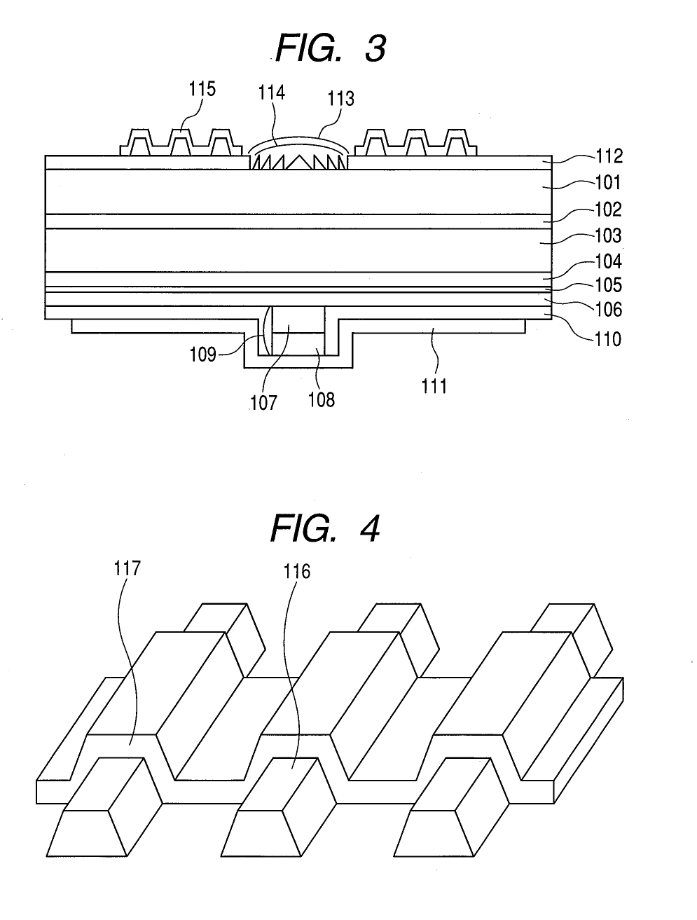

Next, in accordance with a lithographic technique using electron beam or ultraviolet light, there is formed in the through hole a concentric or elliptic diffraction lens 114 having such a sectional shape as shown in FIG. 3 and with a central axis matching the post-like structure. The diffraction lens of such a sectional shape can be formed in high reproducibility by a reduced projection printing method using a photomask modulated in electron beam exposure strength or transmittance. The optical axis of the diffraction lens and that of the post-like structure can be aligned with an accuracy of about 1 μm by means of an exposure unit having a both-side aligning function. Anti-reflection coating constituted by a thin film of silicon oxide and titanium oxide is formed on the surface of the diffraction lens in such a manner that a reflection loss is 1% or less in a silicone-gel-applied condition to be described later.

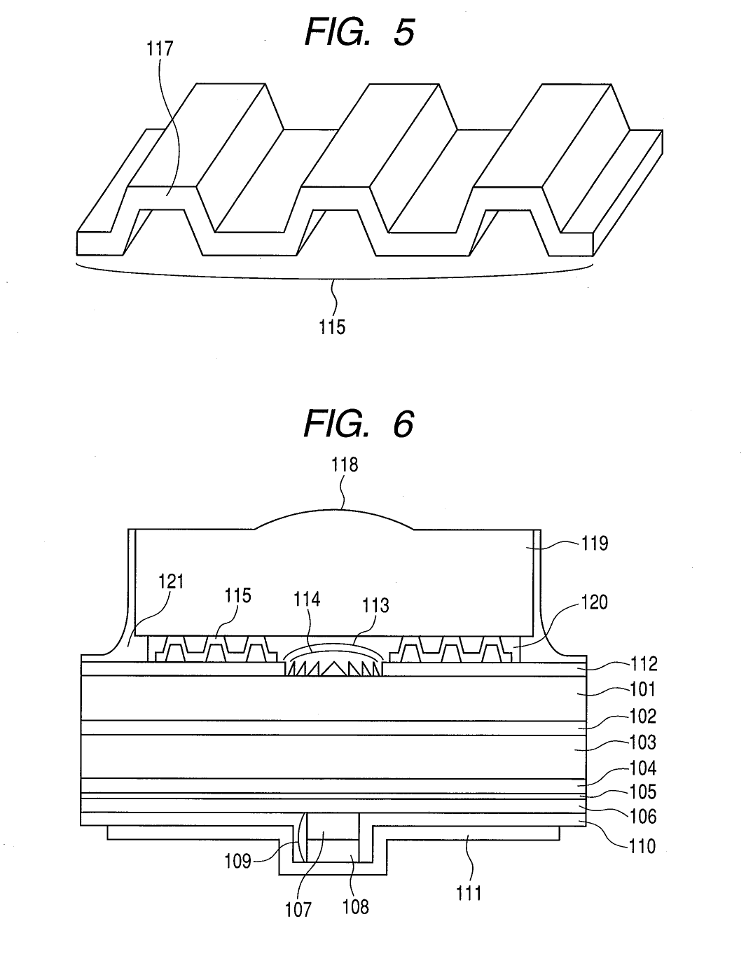

Then, a plated spring 115 for spacing adjustment is formed on the back surface of the wafer by electrolytic plating of copper. This structure is of such a shape as shown in FIG. 5. More specifically, first such photo resist ridges (15 μm thick) 116 as shown in FIG. 4 are formed and a gold electrode is vapor-deposited throughout the entire wafer including the surfaces of the photo resist ridges 116, then a copper plating film (5 μm thick) 117 extending in a direction orthogonal to the photo resist ridges is formed again using the resist process, followed by removal of gold and photo resist ridges exclusive of the plated area to afford such a shape as shown in FIG. 5. With void portions underlying the copper plating film 117, the overlying copper plating film 117 deforms itself in accordance with an external force and thus functions as the plated spring 115. As the material of the plated spring 115 it is suitable to use copper strong in elasticity. However, gold may be used when importance is attached to corrosion resistance, or an alloy containing tin as a principal component may be used when importance is attached to plasticity on heating. In both cases it is possible to achieve respective desired spacing adjusting functions. Such a light emitting device is shown as a single device in FIGS. 1 to 5, but in the actual fabrication process such light emitting devices are arranged in the form of a two-dimensional array through a certain spacing on an InP substrate having a diameter of 2 to 3 inches.

Next, using silicone-gel 120, a micro lens array 119 having micro lenses 118 is bonded to the position corresponding to the above two-dimensional array to form such a light emitting composite optical device as shown in FIG. 6. A silicone-gel stock solution is applied to the back surface of the InP substrate 101 fabricated in the above process and thereafter the micro lens array 119 is laminated to the substrate. At this time, the distance between the micro lens array 119 and the InP substrate 101 is roughly determined to be about 20 μm by the height of the plated spring 115. As the silicone-gel 120 there is used one having been adjusted to a refractive index of 1.45 to match quartz glass which is a substrate of the micro lens array 119. As a result, a refractive index boundary surface becomes only the surface of the InP substrate, thus making it possible to prevent the occurrence of stray light caused by multiple reflection of light. The wafer in this state is baked at 90° C. for about 1 hour to cure the silicone-gel 120 and in this state other glass and silicon gel than in the micro lenses 118-formed area are removed until reaching the InP substrate 101. Subsequently, UV curing resin 121 is filled into this portion and baked at 90° C. for about 1 hour so as to be cured temporarily. The thus-formed laminated structure of lens-integrated light emitting devices and micro lenses is diced into individual light emitting devices.

Usually, such lamination of wafers formed with semiconductor or optical devices is performed using an optical adhesive or resin such as polyimide resin. However, these adhesives are high in hardness after curing and there remains no flexibility; besides, their thermal expansion coefficients are nearly ten times larger than those of semiconductor and quartz wafers, thus causing the generation of stress. Particularly, in the case of the present invention, since optical devices are formed also on the back surface of the InP substrate as an adhesive surface, it is necessary that a spacing of 10 μm or more be ensured between the wafer surfaces to be laminated. With a conventional bonding method, problems have occurred. On the other hand, if the silicone-gel 120 in this embodiment is used as an adhesive medium, a certain flexibility is ensured even after curing of the silicone-gel 120, so that the stress induced by thermal expansion for example is absorbed by the silicone-gel 120 and thus can be prevented from exerting a bad influence on the characteristics of the composite optical devices.

In the devices thus fabricated, a beam radiation direction error can be reduced to about 3′ or less. However, as to the parallelism of collimated beam there still remain variations of 30′ or so because there are substrate roll and thickness error of InP substrate and glass substrate. Thus, in applications where the beam condensability becomes an issue, the error in question is still at a level requiring re-adjustment by additional optics. In connection with such a beam condensability error, by applying a vertical force to the plated spring 115 to compress the spring with the laser ON and by radiating ultraviolet light when an optimum position has been reached, allowing the UV curing resin 121 to cure completely, thereby fixing the lenses completely, it is possible to effect fabrication of the devices in high reproducibility. Because the adhesive is silicone-gel, flexibility is not lost even after the division of composite optical devices, thus making it possible to effect such a fine adjustment easily.

In the case of a trial-manufactured semiconductor laser, oscillation occurred continuously at a threshold current of about 10 mA and at room temperature. Oscillation wavelength was about 1.3 μm and oscillation occurred stably at a single lateral mode up to a maximum light output of 30 mW. An azimuth error of the radiated laser beam and variations in beam spread angle were each not larger than 3′.

### Second Embodiment

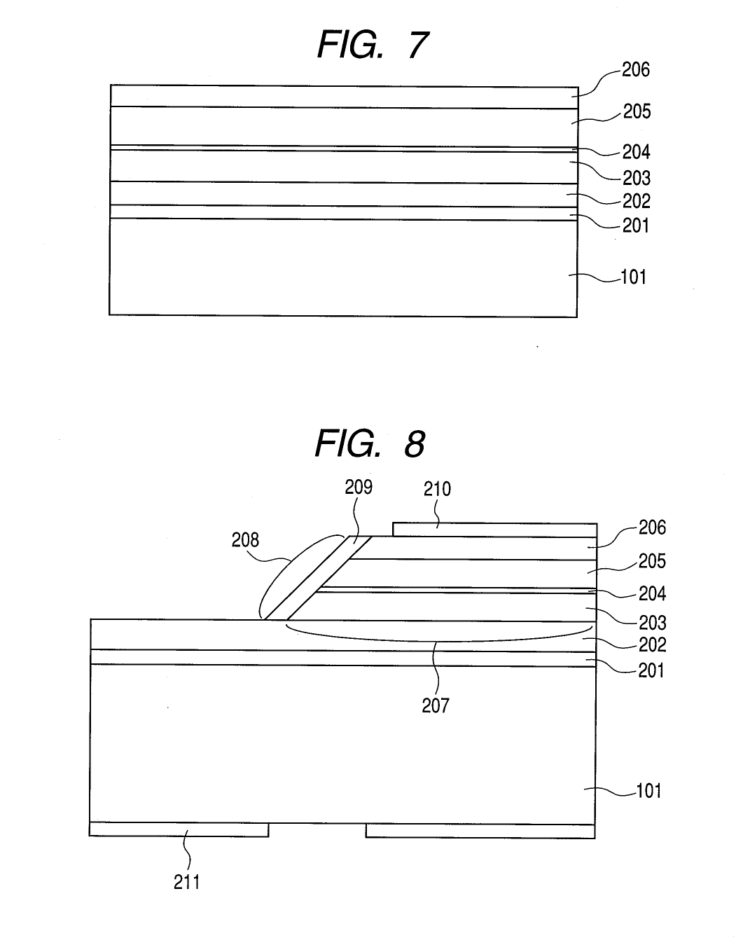

A second embodiment of the present invention will now be described in accordance with a device fabrication procedure in which a semiconductor light emitting device is constituted as an AlGaInAs semiconductor laser with a wavelength of 1300 nm. First, such single-crystal multilayers as shown in FIG. 7 are formed on an n-InP substrate 101 by metal organic chemical vapor deposition. In forming the single crystal multilayer film, there first is formed a Bragg reflector 202 having an optical length of ¼ thick wavelength, which lattice-matches InP. The Bragg reflector 202 is constituted by a laminated film of n-InGaAs an n-InAlAs and has a reflectance of 70%. Subsequently, an n-InP lower cladding layer 203, a strained quantum well active layer 204 composed of an InGaAlAs strained barrier layer (band gap 132 eV, barrier layer thickness 8 nm) and an InGaAlAs strained quantum well layer (band gap 0.87 eV, well layer thickness 6 nm), a p-InP upper cladding layer 205, and a p-InGaAs contact layer 206, are formed in order by crystal growth in accordance with MOVPE (Metal Organic Chemical Vapor Deposition).

Next, with an insulating film or the like as a mask, such a ridge 207 as shown in FIG. 8 is formed by a photoetching process. The etching may be conducted by any method. As well as photoetching, there also may be adopted, for example, a wet process, RIE (Reactive Ion Etching), RIBE (Reactive Ion Beam Etching), or ion milling. Etching is performed so as to stop halfway of the p-InP cladding layer 205 lest it should reach the strained quantum well active layer 14.

Then, with an insulating film as a mask and at an optical resonator angle of 45°, etching is performed up to the lower cladding layer 203 to form a 45° reflective surface. Thereafter, a high reflection film 209 constituted by a periodic film of a non-crystalline silicon film and a silicon dioxide film is formed to afford a 45° tilted mirror 208. Subsequently, there are formed a p-type ohmic contact 210 on an upper surface of the contact layer 206 and an n-type ohmic contact 211 on a back surface of a substrate 8. The back position of the substrate 101 opposed to the 45° tilted mirror 208 is masked with an oxide beforehand and the n-type ohmic contact 211 is removed by lift-off to form a through hole 113.

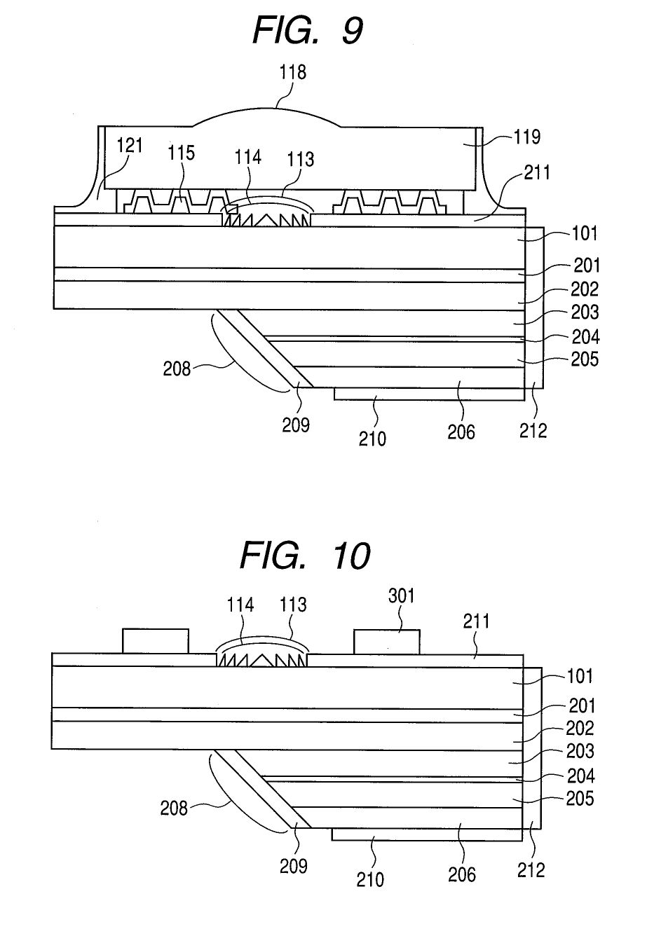

Next, a concentric or elliptic diffraction lens 114 having such a sectional shape as shown in FIG. 9 and with a central axis matching the 45° tilted mirror 208 at its reflective surface is formed in the through hole 113 by lithography using electron beam or ultraviolet light. The diffraction lens of such a sectional shape can be formed in high reproducibility by a reduced projection printing method using a photomask modulated in electron beam exposure strength or transmittance. By forming the diffraction lens in an elliptic shape, it is possible to eliminate astigmatism of the semiconductor laser or transform an elliptic beam radiated from the semiconductor laser into a truly round beam. The optical axis of the diffraction lens and that of the 45° tilted mirror 208 can be aligned with each other with an accuracy of about 1 μm by means of an exposure unit having a both-side position aligning function. Anti-reflection coating constituted by a thin film of silicon oxide and titanium oxide is formed on the surface of the diffraction lens in such manner that a reflection loss is 1% or less in a silicone-gel-applied condition to be described later. Next, by electrolytic plating of copper, a plated spring 115 for spacing adjustment is formed on the wafer back surface. This structure is fabricated in accordance with the same procedure as in FIGS. 4 and 5 referred to above in the first embodiment.

Then, using silicone-gel 120, a micro lens array 119 having micro lenses 118 is bonded the position corresponding to both the 45° tilted mirror 208 and the diffraction lens 113. A silicone stock solution is applied to the back surface of the InP substrate 101 fabricated in the above process and thereafter the micro lens array 119 is laminated to the substrate back surface. At this time, the distance between the micro lens array 119 and the InP substrate 101 is roughly determined to about 20 μm by the height of the plated spring 115. As the silicone-gel 120 there is used one having been adjusted to a refractive index of 1.45 to match quartz glass which is a substrate of the micro lens array 119. As a result, a refractive index boundary surface becomes only the surface of the InP substrate, thus making it possible to prevent the occurrence of stray light caused by multiple reflection of light.

The wafer in this state is baked at 90° C. for about 1 hour to cure the silicone-gel 120 and in this state other glass and silicone-gel than in the micro lenses 118-formed area are removed until reaching the InP substrate 101. Thereafter, UV curing resin 121 is filled into this portion and baked at 90° C. for about 1 hour so as to be cured temporarily. The thus-formed laminated structure of lens-integrated light emitting devices and micro lenses is divided by cleavage into individual light emitting devices. On a cleavage plane serving as a second reflective surface of the optical resonator there is formed a high reflection film 212 constituted by a thin film of silicon oxide and titanium oxide and having a reflectance of 99%.

In the device thus fabricated, a beam radiation direction error can be reduced to about 3′ or less. However, as to the parallelism of collimated beam there still remain variations of 30′ or so because there are substrate roll and thickness error of InP substrate and glass substrate. Thus, in applications where the beam focusing property becomes an issue, the error in question is still at a level requiring re-adjustment by additional optics. In connection with such a beam condensability error, by applying a vertical force to the plated spring 115 to compress the spring with the laser ON and by radiating ultraviolet light when an optimum position has been reached, allowing the UV curing resin 121 to cure completely, thereby fixing the lenses completely, it is possible to effect fabrication of the devices in high reproducibility.

The semiconductor laser thus fabricated can effect laser oscillation by a light feedback mechanism formed by the Bragg reflector which reflects a laser beam to the optical resonator through the cleavage plane and a 135° tilted mirror. Oscillation occurs continuously at a threshold current of about 10 mA and at room temperature. Oscillation wavelength is about 1.3 μm and oscillation occurs stably at a single lateral mode up to a maximum light output of 30 mW. An azimuth error of the radiated laser beam and variations in beam spread angle are each not larger than 3′.

### Third Embodiment

As a third embodiment of the present invention there is shown an example in which, instead of the plated spring, a foamed resin is used in the bonding portion between InP substrate and glass substrate. In this embodiment, the fabrication of light emitting devices on an InP substrate 101 is performed in the same way as in the second embodiment. Next, foamed silicone 301 is applied at a thickness of about 10 μm to the back surface of the substrate 101 and is allowed to foam and cure. Then, the foamed silicone 301 is subjected to photolithography so as to remain at only a portion exclusive of the portion of light emitting devices and lenses, affording the structure of FIG. 10. Under the foaming action, the foamed silicone after curing has a thickness of about 20 μm, still possessing a spongy flexibility permitting adjustment of the spacing between two wafers.

Next, using silicone-gel 120, a micro lens array 119 having micro lenses is bonded to the position corresponding to the 45° tilted mirror 208 and diffraction lens 113. A silicone-gel stock solution is applied to the back surface of the InP substrate 101 fabricated in the above process and thereafter the micro lens array 119 is laminated to the substrate. At this time, the distance between the micro lens array 119 and the InP substrate 101 is roughly determined to be about 20 μm by the height of the plated spring 115. As the silicone-gel 120 there is used one having been adjusted to a refractive index of 1.45 to match quartz glass which is a substrate of the micro lens array 119. As a result, a refractive index boundary surface becomes only the surface of the InP substrate, thus making it possible to prevent the occurrence of stray light caused by multiple reflection of light.

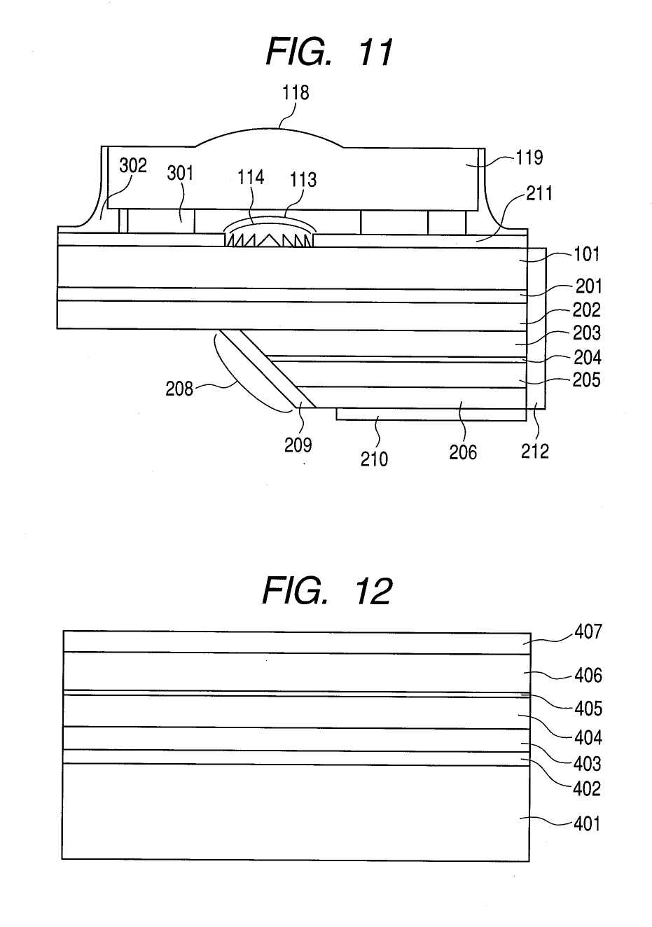

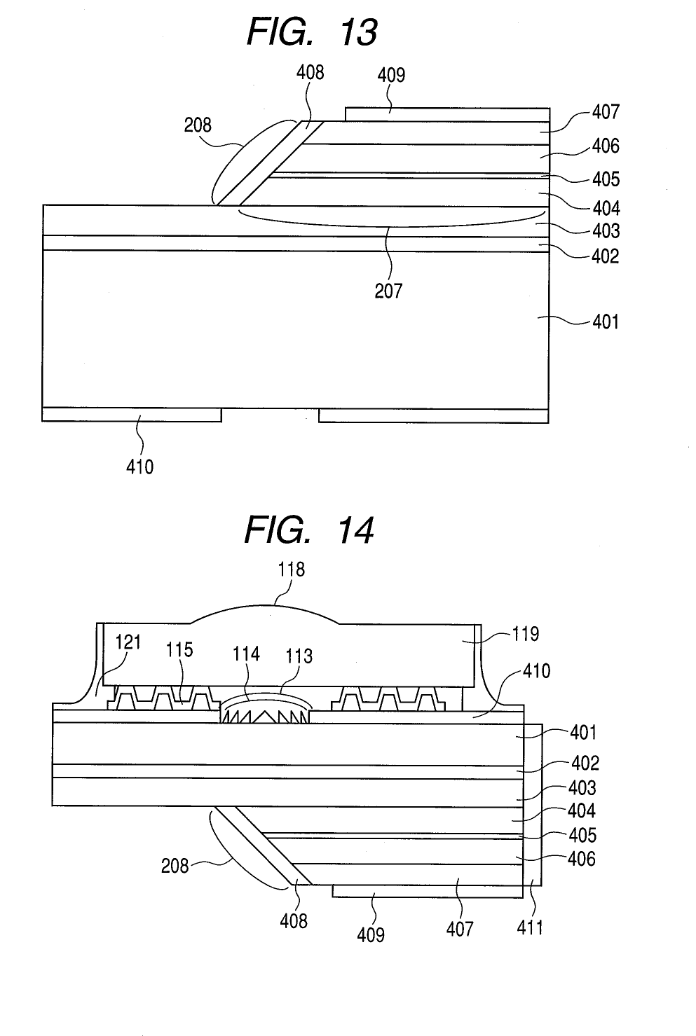

The wafer in this state is baked at 90° C. for about 1 hour to cure the silicone-gel 120 and in this state other glass and silicone-gel than in the micro lenses 118-formed area are removed until reaching the InP substrate 101. Subsequently, silicone 302 with vulcanized agent is filled into this portion and baked at 90° C. for about 1 hour so as to be cured temporarily. The thus-formed laminated structure of lens-integrated light emitting devices and micro lenses is divided by cleavage into such individual light emitting devices as shown in FIG. 11. On a cleavage plane serving as a second reflective surface of the optical resonator there is formed a high reflection film 212 constituted by a thin film of silicon oxide and titanium oxide and having a reflectance of 99%.

In the devices thus fabricated, a beam radiation direction error can be reduced to about 3′ or less. However, as to the parallelism of collimated beam there still remain variations of 30′ or so because there are substrate roll and thickness error of InP substrate and glass substrate. Thus, in applications where the beam condensability becomes an issue, the error in question is still at a level requiring re-adjustment by additional optics. In connection with such a beam condensability error, by applying a vertical force to the foamed silicone 301 to compress the foamed silicone with the laser ON and by conducting a heat treatment at about 160° C. when an optimum position has been reached, allowing the silicone 302 with vulcanized agent to cure completely, thereby fixing the lenses, it is possible to effect fabrication of the devices in high reproducibility. In the case of a trial-manufactured semiconductor laser, oscillation occurred continuously at a threshold current of about 10 mA and at room temperature. Oscillation wavelength was about 1.3 μm and oscillation occurred stably at a single lateral mode up to a maximum light output of 30 mW. An azimuth error of the radiated laser beam and variations in beam spread angle were each not larger than 3′.

### Fourth Embodiment

A fourth embodiment of the present invention will now be described in accordance with a device fabrication procedure in which a semiconductor light emitting device is constituted as an AlGaInN semiconductor laser with a wavelength of 405 nm. First, as shown in FIG. 10, an n-type GaN buffer layer 402 (0.2 μm) and a Bragg reflector 403 constituted by a laminated film of n-GaAlN and n-GaN and having an optical length of ¼ thick wavelength are formed on an n-type GaN substrate 401 (crystal orientation (1-100) plane) in accordance with metal organic chemical vapor deposition. The Bragg reflector 403 has a reflectance of 70%. An n-type Al_{0.08}Ga_{0.92} N cladding layer 404 (Si doped, n=1×10¹⁸ cm⁻³, 1.2 μm), GaInN/GaN multi quantum well active layer 405, p-type GaN/AlGaN super lattice layer 406 (Mg doped, p=7×10¹⁷ cm⁻³, 0.5 μm), and p-type cap layer 407 (Si doped, p=1×10¹⁹ cm⁻³, 0.1 μm), are formed in order by crystal growth.

With an insulating film as a mask, an optical resonator is subjected to mesa-etching at an angle of 45° up to the n-type Al_{0.08}Ga_{0.92}N cladding layer 404 to form a reflective surface and a high reflection film 408 constituted by a periodic film of a non-crystalline silicon film and a silicon dioxide film is formed on the reflective surface, affording a 45° tilted mirror 208. Thereafter, a p-type ohmic contact 409 is formed on an upper surface of the cap layer 407 and an n-type ohmic contact 410 is formed on a back surface of the substrate 401. The back surface of the substrate 401 is masked with an oxide beforehand at the position opposed to the 45° tilted mirror 208 and the n-type ohmic contact 410 is removed by lift-off to form a through hole 113, affording such a structure as shown in FIG. 11. Next, a concentric or elliptic diffraction lens 114 having such a sectional shape as shown in FIG. 12 and with a central axis matching the 45° tilted mirror 208 is formed in the through hole 113 by a lithography technique using electron beam or ultraviolet light. The diffraction lens of such a sectional shape can be formed in high reproducibility by a reduced projection printing method using a photomask modulated in electron beam exposure strength or transmittance. The optical axis of the diffraction lens and that of the 45° tilted mirror 208 can be aligned with an accuracy of about 1 μm by means of an exposure unit having a both-side aligning function. Anti-reflection coating constituted by a thin film of silicon oxide and titanium oxide is formed on the surface of the diffraction lens in such a manner that a reflection loss is 1% or less in a silicone-gel-applied condition to be described later.

Then, a plated spring 115 was formed on the back surface of the wafer by electrolytic plating of copper. This structure is fabricated in accordance with the same procedure as in FIGS. 4 and 5 described above in the first embodiment.

Next, using silicone-gel 120, a micro lens array 119 having micro lenses 118 is bonded to the position corresponding to the 45° tilted mirror 208 and the diffraction lens 113. A silicone-gel stock solution is applied to the back surface of the InP substrate 101 fabricated in the above process and thereafter the micro lens array 119 is laminated to the substrate. At this time, the distance between the micro lens array 119 and the InP substrate 101 is roughly determined to be about 30 μm by the height of the plated spring 115. As the silicone-gel 120 there is used one having been adjusted to a refractive index of 1.45 to match quartz glass which is a substrate of the micro lens array 119. As a result, a refractive index boundary surface becomes only the surface of the InP substrate, thus making it possible to prevent the occurrence of stray light caused by multiple reflection of light.

The wafer in this state is baked at 90° C. for about 1 hour to cure the silicone-gel 120 and in this state other glass and silicone-gel than in the micro lenses 118-formed area are removed until reaching the InP substrate 101. Subsequently, UV curing resin 121 is filled into this portion and baked at 90° C. for about 1 hour so as to be baked temporarily. The thus-formed laminated structure of lens-integrated light emitting devices and micro lenses is divided by cleavage into individual light emitting devices. A high reflection film 411 constituted by a thin film of silicon oxide and titanium oxide and having a reflectance of 99% is formed on a cleavage plane serving as a second reflective surface of the optical resonator.

In the devices thus fabricated, a beam radiation direction error can be reduced to about 3′ or less. However, as to the parallelism of collimated beam there still remain variations of 30′ or so because there are substrate roll and thickness error of InP substrate and glass substrate. Thus, in applications where the beam condensability becomes an issue, the error in question is still at a level requiring re-adjustment by additional optics. In connection with such a beam condensability error, by applying a vertical force to the plated spring 115 to compress the spring with the laser ON and by radiating ultraviolet light when an optimum position has been reached, allowing the UV curing resin 121 to cure completely, thereby fixing the lenses completely, it is possible to effect fabrication of the devices in high reproducibility.

In the case of a trial-manufactured semiconductor laser, oscillation occurred continuously at a threshold current of about 10 mA and at room temperature. Oscillation wavelength was about 405 nm and oscillation occurred stably at a single lateral mode up to a maximum light output of 30 mW. An azimuth error of the radiated laser beam and variations in beam spread angle were each not larger than 3′.

### Fifth Embodiment

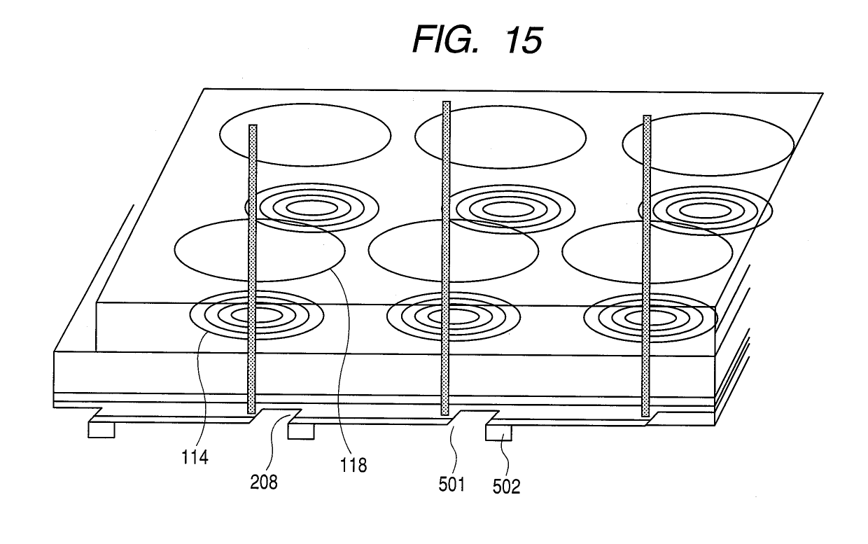

The lens-integrated composite optical device of the present invention makes it possible to afford a laser beam superior in uniformity, so by forming plural semiconductor lasers on a single chip and focusing laser beams emitted from those devices to a single focal point it is also possible to effect a high density of beam condensing. The structure of the semiconductor laser wafer according to the present invention is the same as in the third embodiment, but in this fifth embodiment a 135° tilted mirror 501 is formed simultaneously with the 45° tilted mirror 208. Light beams bent by the 135° tilted mirror 501 and the 45° tilted mirror 208 are reflected respectively by the Bragg reflector 403 formed on the substrate side and a reflection control film 502 formed on a wafer surface which overlies the 135° tilted mirror 501, the reflection control film 502 being constituted by a multilayer film of silicon oxide and titanium oxide, to afford such a structure as shown in FIG. 15 which constitutes a optical resonator.

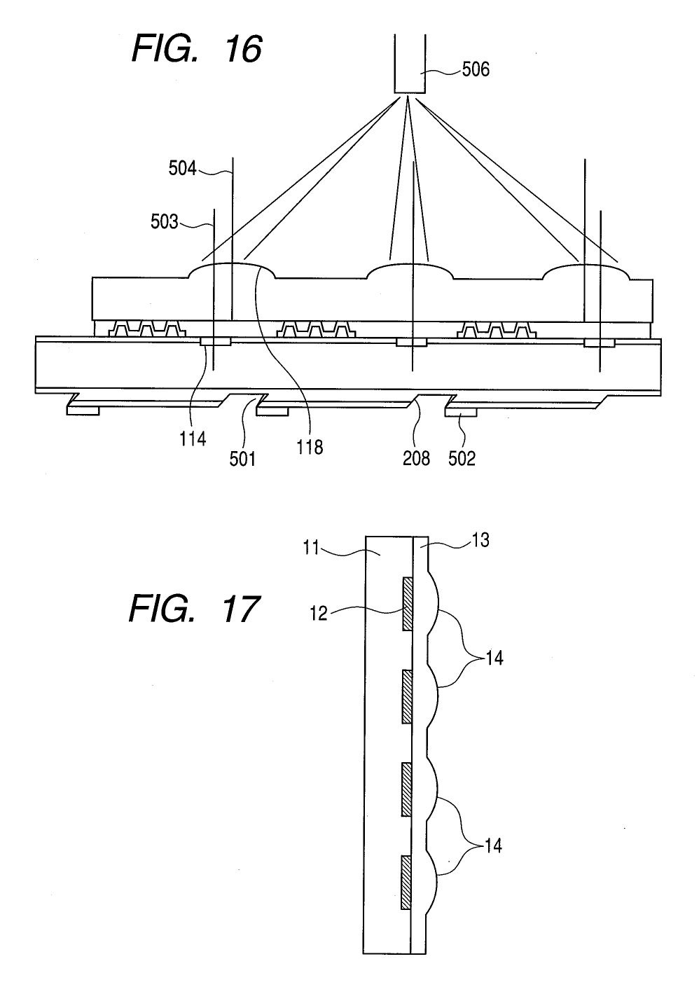

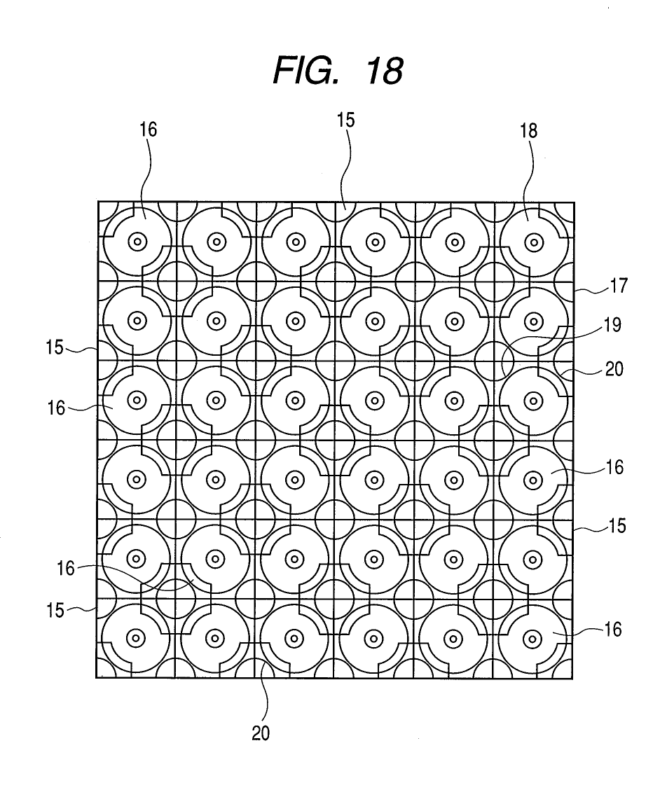

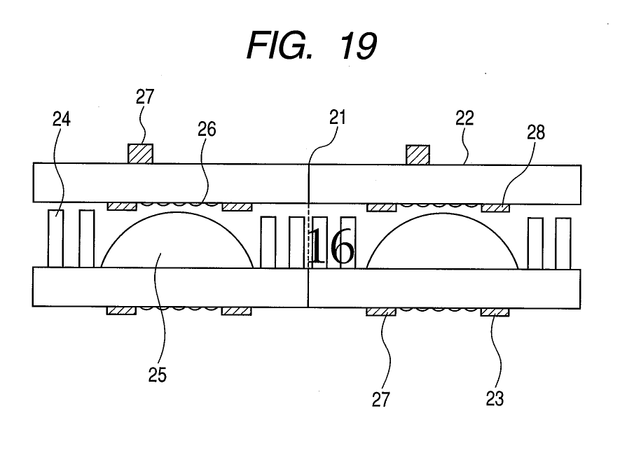

The first to fourth embodiments aimed at obtaining a collimated beam with use of lenses integrated in semiconductor lasers, but in this fifth embodiment strong laser beams are focused to one point to excite an optical fiber laser beam by a combination of plural light emitting devices and lenses provided on a single chip. More specifically, the laser composite optical device according to this embodiment has plural optical resonators within a single laser chip. In these resonators, an optical axis 503 of laser and first lens and an optical axis 504 of laser and second lens are dislocated from each other correspondingly to the respective positions as in FIG. 16. In this configuration, laser beams 505 emitted from a two-dimensional array are focused to one spatial point. One end face of a rare earth doped optical fiber 506 is disposed at this focal point, causing 2 W laser beams emitted from ten devices to be introduced into a single optical fiber. According to this embodiment, a laser beam having a wavelength of 440 nm enters a 2 W optical fiber, and with this as a pumping source, it is possible to excite laser beams of 630 nm and 525 nm within the optical fiber. According to this configuration there are obtained 500 mW white laser beams of 440 nm, 525 nm, and 630 nm, in wavelength.

What is claimed is:

1. An optical module comprising:
a laser device adapted to emit a laser beam from a convex surface and including a horizontal resonator surface-emitting structure provided with a first lens through which an optical axis of the laser beam passes; and
a second lens through which the laser beam having passed through the first lens passes,
wherein a surface opposed to the second lens-provided surface and the surface provided with the first lens are bonded together through a first adhesive transparent to the laser beam.

2. An optical module according to claim 1, wherein one of the first lens and the second lens is a diffraction lens.

3. An optical module according to claim 1, wherein the adhesive is a gelatinous material able to retain flexibility also after the bonding.

4. An optical module according to claim 1, wherein the surface opposed to the second lens-provided surface and the surface provided with the first lens are constituted by a spacer higher in elastic force than the adhesive.

5. An optical module according to claim 4, wherein the spacer is a metal layer formed by a plating method or a porous resin.

6. An optical module according to claim 1, wherein the laser device and the second lens are fixed together through a second adhesive different from the first adhesive.

7. An optical module according to claim 6, wherein the second adhesive is an UV curing resin or silicone cured by a vulcanizing treatment.

8. An optical module according to claim 1, comprising a plurality of the horizontal resonator surface-emitting structures.

9. An optical module according to claim 8, wherein light beams emitted from the horizontal resonator surface-emitting structures are focused by second lenses provided in the horizontal resonator surface-emitting structures respectively.
